(19) United States
(12) Patent Application Publication
(10) Pub. No.: US 2025/0061950 A1
(43) Pub. Date: Feb. 20, 2025

(54) POWER CONTROL APPARATUS FOR NON-VOLATILE MEMORY

(71) Applicant: eMemory Technology Inc., Hsin-Chu (TW)

(72) Inventor: Yu-Hsuan CHENG, Hsinchu County (TW)

(21) Appl. No.: 18/790,228

(22) Filed: Jul. 31, 2024

Related U.S. Application Data
(60) Provisional application No. 63/532,701, filed on Aug. 15, 2023.

(51) Int. Cl. G11C 16/30; G11C 5/14; G11C 16/08

(52) U.S. Cl. CPC G11C 16/30; G11C 5/147; G11C 16/08

(57) ABSTRACT

A power control apparatus for a non-volatile memory includes a reference voltage generator, an adjusting circuit and a switching circuit. The adjusting circuit receives a deep standby signal and an operation signal. The adjusting circuit generates a mode indicating signal and a control signal. The switching circuit is connected with a first node. A voltage at the first node is an operation voltage. In a deep standby mode, the ground voltage is connected with the first node through the switching circuit. In a normal operation mode, a supply voltage is connected with the first node through the switching circuit. In a standby mode, an adjustable resistance path is connected between the supply voltage and the first node. The resistance value of the adjustable resistance path is adjusted according to the control signal until the operation voltage is equal to the reference voltage.

This application claims the benefit of U.S. provisional application Ser. No. 63/532,701, filed Aug. 15, 2023, the subject matters of which is incorporated herein by reference.

### FIELD OF THE INVENTION

The present invention relates to a circuit in a non-volatile memory, and more particularly to a power control apparatus for a non-volatile memory.

### BACKGROUND OF THE INVENTION

As is well known, non-volatile memories can store data for a long time. Consequently, non-volatile memories have been widely used in electronic products. Generally, the non-volatile memory can be operated in a deep standby mode, a standby mode or a normal operation mode. The operations of the non-volatile memory in different modes will be described as follows.

In deep standby mode, the non-volatile memory is disabled. In other words, the non-volatile memory does not receive an operation voltage. That is, the operation voltage is 0V when the non-volatile memory is in the deep standby mode. In the normal operation mode, the non-volatile memory receives the operation voltage, and the non-volatile memory is operated normally. For example, the non-volatile memory is selectively subjected to a program operation, a read operation or an erase operation. In standby mode, the non-volatile memory receives the operation voltage, but no operation is performed on the non-volatile memory.

As mentioned above, the non-volatile memory still receives the operation voltage in standby mode. Consequently, when the standby mode is switched to the normal operation mode, the program operation, the read operation or the erase operation can be performed on the non-volatile memory immediately. Furthermore, when the standby mode is switched to the deep standby mode, the non-volatile memory stops receiving the operation voltage, and the non-volatile memory is disabled.

Although the non-volatile memory is not subjected to any operation in the standby mode, the circuits in the non-volatile memory still receive the operation voltage and generate leakage currents. The generation of the leakage currents may result in additional power loss.

### SUMMARY OF THE INVENTION

An embodiment of the present invention provides a power control apparatus for a non-volatile memory. The power control apparatus includes a reference voltage generator receiving an adjustment signal, wherein when the adjustment signal is activated, the reference voltage generator provides a reference voltage; an adjusting circuit generating a mode indicating signal, the adjustment signal and a control signal, wherein the mode indicating signal indicates that the non-volatile memory is in a deep standby mode, a normal operation mode or a standby mode, wherein the adjusting circuit is connected with the reference voltage generator, and the adjusting circuit receives the reference voltage; and a switching circuit receiving a supply voltage, a ground voltage, the mode indicating signal and the control signal, wherein an output terminal of the switching circuit is connected with a first node, a voltage at the first node is an operation voltage, and a load is connected with the first node. The switching circuit comprises a first switching path, a second switching path and a third switching path, wherein the reference voltage is lower than the supply voltage and the reference voltage is higher than the ground voltage. When the non-volatile memory is in the deep standby mode, the first switching path is activated according to the mode indicating signal, so that the ground voltage is connected with the first node and the operation voltage is equal to the ground voltage. When the non-volatile memory is in the normal operation mode, the second switching path is activated according to the mode indicating signal, so that the supply voltage is connected with the first node and the operation voltage is equal to the supply voltage. The third switching path is an adjustable resistance path. When the non-volatile memory is in the standby mode, the adjustment signal is activated, and the third switching path is activated according to the mode indicating signal, so that the third switching path is connected between the supply voltage and the first node, wherein a resistance value of the adjustable resistance path is adjusted by the adjusting circuit according to the control signal until a magnitude of the operation voltage is equal to a magnitude of the reference voltage.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic circuit block diagram illustrating the architecture of a non-volatile memory of the present invention according to an embodiment of the present invention;

FIG. 2A is a schematic circuit diagram illustrating a power control apparatus for the non-volatile memory according to a first embodiment of the present invention;

FIG. 2B is a schematic timing waveform diagram illustrating associated signals of the power control apparatus according to the first embodiment of the present invention;

FIG. 3A is a schematic circuit diagram illustrating a first exemplary switching circuit of the power control apparatus according to the first embodiment of the present invention;

FIG. 3B is a schematic circuit diagram illustrating a second exemplary switching circuit of the power control apparatus according to the first embodiment of the present invention;

FIG. 3C is a schematic circuit diagram illustrating a second exemplary switching circuit of the power control apparatus according to the first embodiment of the present invention;

FIG. 4A is a schematic circuit diagram illustrating a power control apparatus for the non-volatile memory according to a second embodiment of the present invention; and

FIG. 4B is a schematic timing waveform diagram illustrating associated signals of the power control apparatus according to the second embodiment of the present invention.

### DETAILED DESCRIPTION OF PREFERRED EMBODIMENTS

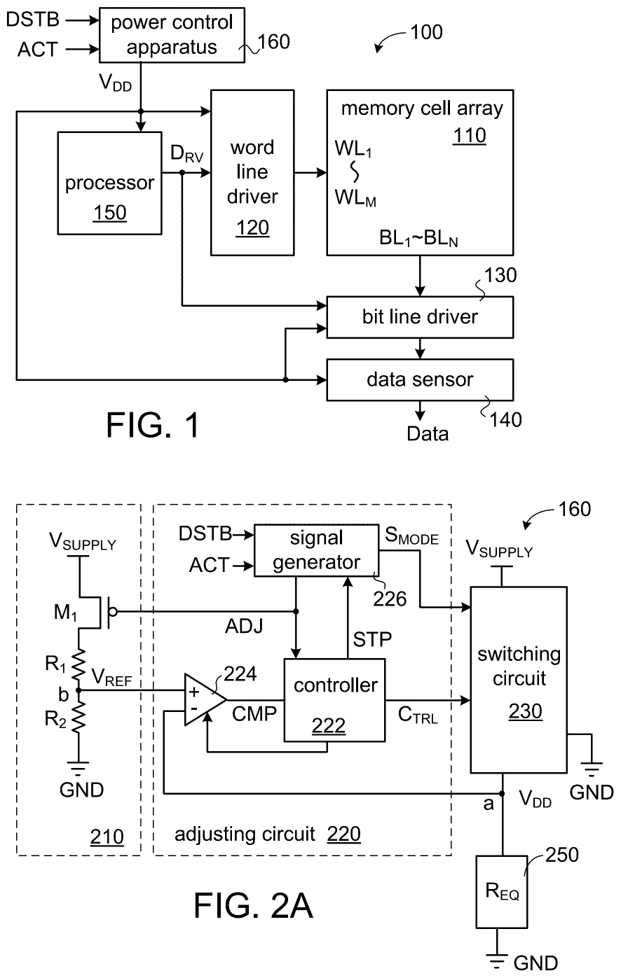

FIG. 1 is a schematic circuit block diagram illustrating the architecture of a non-volatile memory of the present invention according to an embodiment of the present invention. As shown in FIG. 1, the non-volatile memory 100 comprises a memory cell array 110, a word line driver 120, a bit line driver 130, data sensor 140, a processor 150 and a power control apparatus 160.

The memory cell array 110 comprises M×N memory cells in an array arrangement. The M×N memory cells are connected with M word lines WL₁˜WL_{M} and N bit lines BL₁˜BL_{N}. The processor 150 is connected with host (not shown) to receive commands from the host. According to the command, the processor 150 issues a corresponding driving signal D_{RV}. The word line driver 120 and the bit line driver 130 receive the driving signal D_{RV}. The word line driver 120 is connected with the word lines WL₁˜WL_{M}. The bit line driver 130 is connected with the bit lines BL₁˜BL_{N}. According to the driving signal D_{RV}, the word line driver 120 and the bit line driver 130 activate the corresponding word line and the corresponding bit line. In addition, the data sensor 140 is connected with the bit line driver 130.

The power control apparatus 160 outputs an operation voltage V_{DD} to the processor 150, the word line driver 120, the bit line driver 130 and the data sensor 140. For example, when the non-volatile memory 100 is in the normal operation mode, the power control apparatus 160 provides an operation voltage V_{DD} of 1.2V. Consequently, the core logic circuits in the processor 150, the word line driver 120, the bit line driver 130 and the data sensor 140 can be operated.

When the non-volatile memory 100 is in the normal operation mode, the non-volatile memory can be selectively subjected to a program operation, a read operation or an erase operation. For example, in case that the host issues a write command, the processor 150 generates the corresponding driving signal D_{RV} to the word line driver 120 and the bit line driver 130 to perform the program operation on specified memory cells in the memory cell array 110. Similarly, in case that the host issues a read command, the processor 150 generates the corresponding driving signal D_{RV} to the word line driver 120 and the bit line driver 130 to perform the read operation on specified memory cells in the memory cell array 110. After the read operation is completed, the data sensor 140 outputs a read data Data. Similarly, in case that the host issues an erase command, the processor 150 generates the corresponding drive signal D_{RV} to the word line driver 120 and the bit line driver 130 to perform an erase operation on specified memory cells in the memory cell array 110.

According to a deep standby signal DSTB and an operation signal ACT, the non-volatile memory 100 is selectively in a deep standby mode, a normal operation mode or a standby mode. According to the operation mode of the non-volatile memory 100, the power control apparatus 160 provides the appropriate operation voltage V_{DD} to the processor 150, the word line driver 120, the bit line driver 130 and the data sensor 140.

The power control apparatus 160 receives the deep standby signal DSTB and the operation signal ACT. In the deep standby mode, the operation voltage V_{DD} provided by the power control apparatus 160 is 0V. In the normal operation mode, the operation voltage V_{DD} provided by the power control apparatus 160 is 1.2V. In the standby mode, the operation voltage V_{DD} provided by the power control apparatus 160 is higher than 0V and lower than 1.2V. For example, the operation voltage V_{DD} is 1.0V. Consequently, the power loss of the non-volatile memory 100 in the standby mode can be reduced.

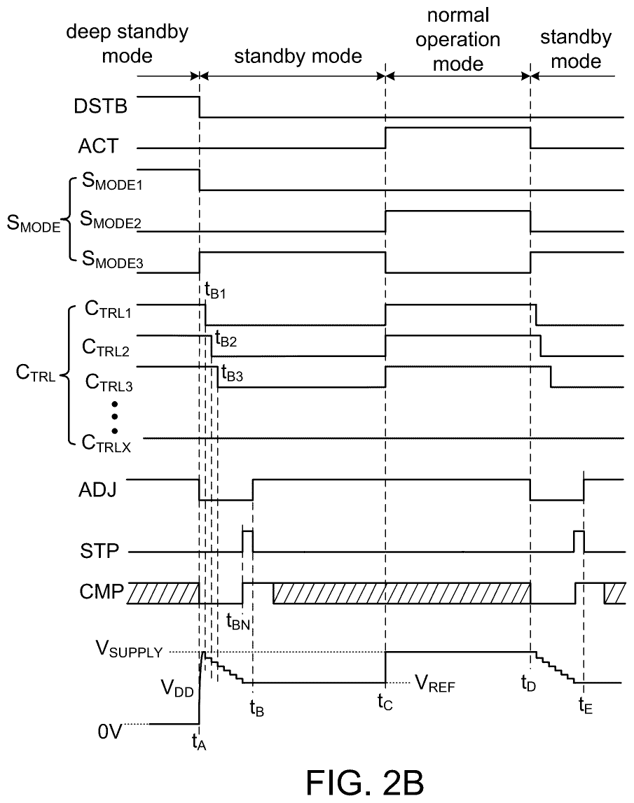

FIG. 2A is a schematic circuit diagram illustrating a power control apparatus for the non-volatile memory according to a first embodiment of the present invention. FIG. 2B is a schematic timing waveform diagram illustrating associated signals of the power control apparatus according to the first embodiment of the present invention.

The power control apparatus 160 comprises a reference voltage generator 210, an adjusting circuit 220 and a switching circuit 230. The output terminal of the switching circuit 230 is connected with the node a. The voltage at the node a is the operation voltage V_{DD}. That is, the output terminal of the switching circuit 230 can output the operation voltage V_{DD}. In addition, the output terminal of the switching circuit 230 is connected with a load 250. The load 250 is regarded as a resistor R_{EQ}. The load 250 includes the processor 150, the word line driver 120, the bit line driver 130 and the data sensor 140 of the non-volatile memory 100. The output terminal of the reference voltage generator 210 can output a reference voltage V_{REF}. The adjusting circuit 220 is connected with the output terminal of the reference voltage generator 210 to receive the reference voltage V_{REF}. The adjusting circuit 220 is further connected with the switching circuit 230. The switching circuit 230 receives a supply voltage V_{SUPPLY} and a ground voltage GND. For example, the supply voltage V_{SUPPLY} is 1.2V, the ground voltage GND is 0V, and the reference voltage V_{REF} is in the range between the supply voltage V_{SUPPLY} and the ground voltage GND. For example, the reference voltage V_{REF} is 1.0V.

The reference voltage generator 210 comprises a transistor M₁ and two resistors R₁ and R₂. The source terminal of the transistor M₁ receives the supply voltage V_{SUPPLY}. The gate terminal of the transistor M₁ receives an adjustment signal ADJ. The first terminal of the resistor R₁ is connected with the drain terminal of the transistor M₁. The second terminal of the resistor R₁ is connected with the node b. The first terminal of the resistor R₂ is connected with the node b. The second terminal of the resistor R₂ receives the ground voltage GND. In addition, the voltage at the node b is the reference voltage V_{REF}.

When the adjustment signal ADJ is activated, the transistor M₁ is turned on, and the reference voltage V_{REF} outputted from the reference voltage generator 210 is equal to [V_{SUPPLY}×R₂/(R₁+R₂)]. In other words, the magnitude of the reference voltage V_{REF} can be determined according to the resistance values of the resistors R₁ and R₂. In an embodiment, the resistors R₁ and R₂ have fixed resistance values. Alternatively, the resistors R₁ and R₂ have variable resistance values.

The adjusting circuit 220 comprises a signal generator 226, a controller 222 and a comparator 224.

The first input terminal of the comparator 224 receives the reference voltage V_{REF}. The second input terminal of the comparator 224 is connected with the node a to receive the operation voltage V_{DD}. The output terminal of the comparator 224 generates a comparison signal CMP.

The signal generator 226 receives the deep standby signal DSTB, the operation signal ACT and a stop signal STP. In addition, the signal generator 226 generates a mode indicating signal S_{MODE} and the adjustment signal ADJ. The mode indicating signal S_{MODE} is used to indicate that the non-volatile memory 100 is in the deep standby mode, the standby mode or the normal operation mode. In the standby mode, the adjustment signal ADJ is activated to start an adjusting period. When the stop signal STP is activated, the adjustment signal ADJ is not activated, and the adjusting period is ended.

The controller 222 receives the adjustment signal ADJ and the comparison signal CMP. In addition, the controller 222 generates a control signal C_{TRL} and the stop signal STP. When the adjustment signal ADJ is activated, the controller 222 starts to change the control signal C_{TRL}. When the comparison signal CMP is activated, the controller 222 no longer changes the control signal C_{TRL}, and the controller 222 activates the stop signal STP. Consequently, the adjustment signal ADJ is inactivated.

When the non-volatile memory 100 is in the deep standby mode or the normal operation mode, the signal generator 226 provides the mode indicating signal S_{MODE} to the switching circuit 230, and the adjustment signal ADJ is not activated. Since the reference voltage generator 210 is disabled, the control signal C_{TRL} is not changed by the controller 222, and the comparator 224 is disabled.

When the non-volatile memory 100 is in the standby mode, signal generator 226 provides the mode indicating signal S_{MODE} to the switching circuit 230, and the adjustment signal ADJ is activated. According to the adjustment signal ADJ, the reference voltage generator 210 is activated, and the controller 222 is activated to enable the comparator 224. Meanwhile, the control signal C_{TRL} is changed by the controller 222. Consequently, the operation voltage V_{DD} outputted from the output terminal of the switching circuit 230 is subjected to the change. For example, when the control signal C_{TRL} is changed, the operation voltage V_{DD} outputted from the output terminal of the switching circuit 230 starts to drop from the supply voltage V_{SUPPLY}.

If the operation voltage V_{DD} is greater than the reference voltage V_{REF}, the comparison signal CMP outputted from the comparator 224 is in a logic low level state. If the operation voltage V_{DD} drops to a voltage level lower than the reference voltage V_{REF}, the comparison signal CMP outputted from the comparator 224 is switched to a logic high level state. Meanwhile, it can be regarded that the magnitude of the operation voltage V_{DD} and the magnitude of the reference voltage V_{REF} are identical.

As mentioned above, when the comparison signal CMP is activated, the controller 222 no longer changes the control signal C_{TRL}, and the controller 222 activates the stop signal STP. Consequently, the comparator 224 is disabled. In other words, when the non-volatile memory 100 is in the standby mode, the adjusting circuit 220 adjusts the operation voltage V_{DD} until the magnitude of the operation voltage V_{DD} and the magnitude of the reference voltage V_{REF} are identical.

The switching circuit 230 receives the supply voltage V_{SUPPLY}, the ground voltage GND, the mode indicating signal S_{MODE} and the control signal C_{TRL}. The switching circuit 230 includes plural switching paths.

In the deep standby mode, a first switching path in the switching circuit 230 is activated according to the mode indicating signal S_{MODE}. Consequently, the ground voltage GND is connected with the output terminal of the switching circuit 230. That is, in the deep standby mode, the operation voltage V_{DD} provided by the switching circuit 230 is 0V.

In the normal operation mode, a second switching path in the switching circuit 230 is activated according to the mode indicating signal S_{MODE}. Consequently, the supply voltage V_{SUPPLY} is connected with the output terminal of the switching circuit 230. That is, in the normal operating mode, the operation voltage V_{DD} provided by the switching circuit 230 is 1.2V.

In the standby mode, a third switching path in the switching circuit 230 is activated according to the mode indicating signal S_{MODE}. Consequently, the third switching path is connected between the supply voltage V_{SUPPLY} and the output terminal of the switching circuit 230. In addition, the third switching path is an adjustable resistance path. The resistance value of the adjustable resistance path is adjusted according to the control signal C_{TRL}. That is, the operation voltage V_{DD} is the voltage division result of the resistance value of the adjustable resistor path and the load (R_{EQ}). Consequently, when the non-volatile memory 100 is in the standby mode, the adjusting circuit 220 adjusts the resistance value of the adjustable resistor path according to the control signal C_{TRL} until the magnitude of the operation voltage V_{DD} and the magnitude of the reference voltage V_{REF} are identical.

Please refer to FIG. 2B. When the deep standby signal DSTB is in the logic high level state and the operation signal ACT is in the logic low level state, the non-volatile memory 100 is in the deep standby mode. When the deep standby signal DSTB is in the logic low level state and the operation signal ACT is in the logic low level state, the non-volatile memory 100 is in the standby mode. When the deep standby signal DSTB is in the logic low level state and the operation signal ACT is in the logic high level state, the non-volatile memory 100 is in the normal operation mode. In addition, the signal generator 226 generates the mode indicating signal S_{MODE} according to the deep standby signal DSTB and the operation signal ACT.

The mode indicating signal S_{MODE} contains a first mode signal S_{MODE1}, a second mode signal S_{MODE2} and a third mode signal S_{MODE3}. When the non-volatile memory 100 is in the deep standby mode, the first mode signal S_{MODE1} is activated, and the first mode signal S_{MODE1} is in the logic high level state. When the non-volatile memory 100 is in the normal operation mode, the second mode signal S_{MODE2} is activated, and the second mode signal S_{MODE2} is in the logic high level state. When the non-volatile memory 100 is in the standby mode, the third mode signal S_{MODE3} is activated, and the third mode signal S_{MODE3} is in the logic high level state.

Please refer to FIG. 2B again. Before the time point t_{A}, the first mode signal S_{MODE1} is activated, and the second mode signal S_{MODE2} and the third mode signal S_{MODE3} are not activated. Under this circumstance, the non-volatile memory 100 is in the deep standby mode.

In the time interval between the time point t_{A} and the time point t_{C}, the third mode signal S_{MODE3} is activated, and the first mode signal S_{MODE1} and the second mode signal S_{MODE2} are not activated. Under this circumstance, the non-volatile memory 100 is in the standby mode.

In the time interval between the time point t_{C} and the time point t_{D}, the second mode signal S_{MODE2} is activated, and the first mode signal S_{MODE1} and the third mode signal S_{MODE3} are not activated. Under this circumstance, the non-volatile memory 100 is in the normal operation mode.

After the time point t_{D}, the third mode signal S_{MODE3} is activated, and the first mode signal S_{MODE1} and the second mode signal S_{MODE2} are not activated. Under this circumstance, the non-volatile memory 100 is in the standby mode.

In the deep standby mode (i.e., before the time point t_{A}), the operation voltage V_{DD} provided by the switching circuit 230 is 0V. In the normal operation mode (i.e., in the time interval between the time point t_{C} and the time point t_{D}), the operation voltage V_{DD} provided by the switching circuit 230 is 1.2V. That is, the operation voltage V_{DD} is equal to the supply voltage V_{SUPPLY}.

In the time interval between the time point t_{A} and the time point t_{C}, the non-volatile memory 100 is in the standby mode. The initial period of the standby mode is an adjusting period. In this embodiment, the time interval between the time point t_{A} and the time point t_{B} is the adjusting period. In the adjusting period, the adjustment signal ADJ is activated and is switched from the logic high level state to the logic low level state. Consequently, the reference voltage generator 210 and comparator 224 are enabled. Furthermore, the control signal C_{TRL} is controlled by the controller 222. Consequently, the resistance value of the adjustable resistance path (i.e., the third switching path) is changed, and the operation voltage V_{DD} outputted from the output terminal of the switching circuit 230 is correspondingly changed. For example, the control signal C_{TRL} contains X control bits C_{TRL1}˜C_{TRLX}, wherein X is a positive integer. In this embodiment, the initial value of control signal C_{TRL} is that all X control bits C_{TRL1}˜C_{TRLX} are in the logic high level state. In case that all of the X control bits C_{TRL1}˜C_{TRLX} are in the logic high level state, the resistance value of the adjustable resistance path is the lowest. As the number of the X control bits C_{TRL1}˜C_{TRLX} in the logic high level state decreases, the resistance value of the adjustable resistance path increases. In case that all of the X control bits C_{TRL1}˜C_{TRLX} are in the logic low level state, the resistance value of the adjustable resistance path is the highest.

Please refer to FIG. 2B again. At the time point t_{A}, all of the X control bits C_{TRL1}˜C_{TRLX} are in the logic high level state, and the resistance value of the adjustable resistance path is the lowest. Consequently, the operation voltage V_{DD} outputted from the output terminal of the switching circuit 230 rapidly rises from 0V in the deep standby mode to the supply voltage V_{SUPPLY}. After the time point t_{A}, the number of the X control bits C_{TRL1}˜C_{TRLX} in the logic high level state gradually decreases. That is, the adjusting circuit 220 gradually adjusts the logic level state of the X control bits from the initial value. Consequently, the resistance value of the adjustable resistance path gradually increases, and the operation voltage V_{DD} gradually decreases.

At the time point t_{A}, the operation voltage V_{DD} outputted from the output terminal of the switching circuit 230 is equal to the supply voltage V_{SUPPLY}. The operation voltage V_{DD} is higher than the reference voltage V_{REF}. The comparison signal CMP is in the logic low level state.

At time point t_{B1}, the control bit C_{TRL1} is changed to the logic low level state, and the other control bits C_{TRL2}˜C_{TRLX} are in the logic high level state. The resistance value of the adjustable resistance path increases, and the operation voltage V_{DD} outputted from the output terminal of the switching circuit 230 decreases. The operation voltage V_{DD} is still higher than the reference voltage V_{REF}. The comparison signal CMP is in the logic low level state.

At time point t_{B2}, the control bits C_{TRL1} and C_{TRL2} are changed to the logic low level state, and the other control bits C_{TRL3}˜C_{TRLX} are in the logic high level state. The resistance value of the adjustable resistance path increases, and the operation voltage V_{DD} outputted from the output terminal of the switching circuit 230 decreases. The operation voltage V_{DD} is still higher than the reference voltage V_{REF}. The comparison signal CMP is in the logic low level state.

Similarly, at the time point t_{B3}, the control bits C_{TRL1}˜C_{TRL3} are changed to the logic low level state, and the other control bits C_{TRL4}˜C_{TRLX} are in the logic high level state. The resistance value of the adjustable resistance path further increases, and the operation voltage V_{DD} outputted from the output terminal of the switching circuit 230 further decreases. The operation voltage V_{DD} is still higher than the reference voltage V_{REF}. The comparison signal CMP is in the logic low level state. For example, the control signal C_{TRL} is changed once approximately every 100 μs. That is, in FIG. 2B, the time period between the time point t_{A} and the time point t_{B1} is approximately 100 μs, the time period between the time point t_{B1} and the time point t_{B2} is approximately 100 μs, and the time period between the time point t_{B2} and the time point t_{B3} is approximately 100 μs.

The rest may be deduced by analogy. For example, the control signal C_{TRL} is continuously changed until the operation voltage V_{DD} is equal to the reference voltage V_{REF} (i.e., at the time point t_{BN}). Meanwhile, the comparison signal CMP is activated and switched to the logic high level state. Consequently, at the time point t_{BN}, the controller 222 no longer changes the control signal C_{TRL}, and the controller 222 activates the stop signal STP.

After the stop signal STP is activated, at the time point t_{B}, the adjustment signal ADJ is changed from the logic low level state to the logic high level state by the signal generator 226. That is, the adjustment signal ADJ is not activated, and the adjusting period is ended. Meanwhile, the operation voltage V_{DD} outputted from the output terminal of the switching circuit 230 is maintained at the reference voltage V_{REF}. That is, after the non-volatile memory 100 enters the standby mode, the power control apparatus 160 will adjust the operation voltage V_{DD} in one adjusting period. At the end of the adjusting period, the operation voltage V_{DD} provided by the power control apparatus 160 is equal to the reference voltage V_{REF}.

At the time point t_{C}, the non-volatile memory 100 is switched from the standby mode to the normal operation mode. Meanwhile, the operation voltage V_{DD} outputted from the output terminal of the switching circuit 230 is switched from the reference voltage V_{REF} to the supply voltage V_{SUPPLY}.

Similarly, at the time point t_{D}, the non-volatile memory 100 is switched from the normal operation mode to the standby mode. In the adjusting period between the time point t_{D} and the time point t_{E}, the operation voltage V_{DD} outputted from the output terminal of the switching circuit 230 starts to drop from the supply voltage V_{SUPPLY} until the operation voltage V_{DD} is equal to the reference voltage V_{REF} (i.e., at the time point t_{E}).

From the above descriptions, the present invention provides a power control apparatus 160 for a non-volatile memory. When the non-volatile memory enters the deep standby mode, the operation voltage V_{DD} provided by the power control apparatus 160 is 0V. When the non-volatile memory enters the normal operation mode, the operation voltage V_{DD} provided by the power control apparatus 160 is equal to the supply voltage V_{SUPPLY}. When the non-volatile memory enters the standby mode, the operation voltage V_{DD} provided by the power control apparatus 160 is equal to the reference voltage V_{REF}. The reference voltage V_{REF} is higher than the ground voltage (0V). The reference voltage V_{REF} is lower than the supply voltage V_{SUPPLY}. Since the operation voltage V_{DD} provided by the power control apparatus 160 is lower than the supply voltage V_{SUPPLY} when the non-volatile memory enters the standby mode, the power loss in the standby mode can be effectively reduced.

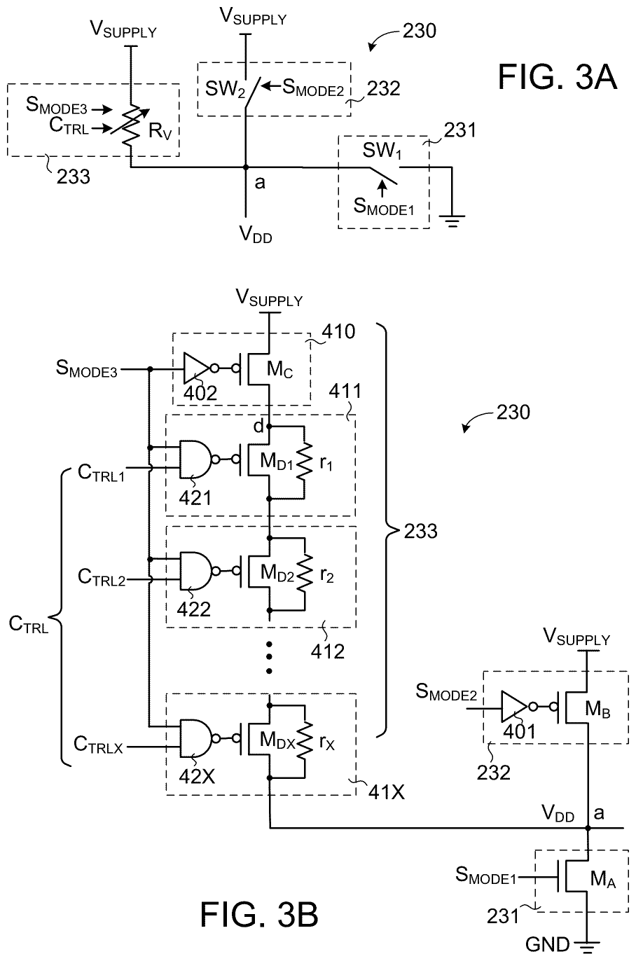

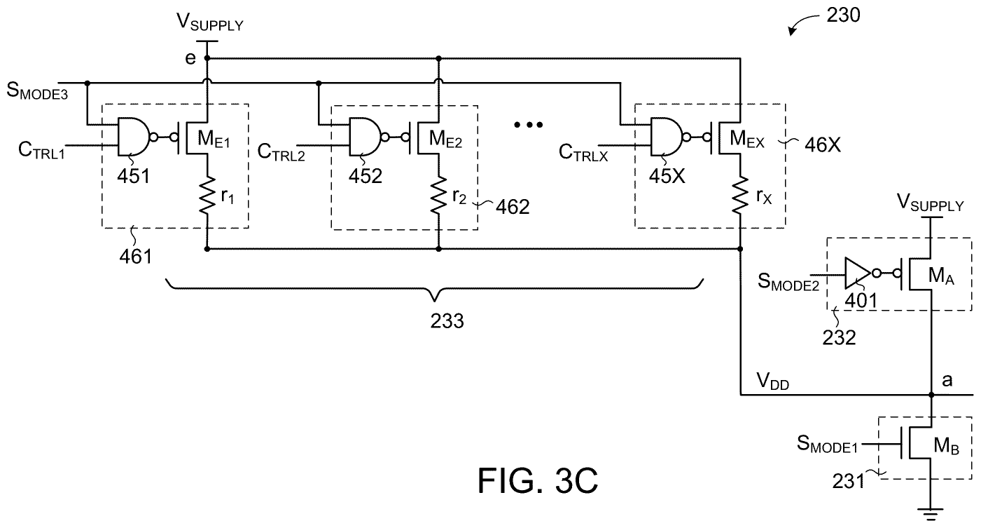

FIG. 3A is a schematic circuit diagram illustrating a first exemplary switching circuit of the power control apparatus according to the first embodiment of the present invention. The node a is the output terminal of the switching circuit 230. The voltage at the node a is the operation voltage V_{DD}.

The first switching path 231 of the switching circuit 230 comprises a switch SW₁. The second switching path 232 of the switching circuit 230 comprises a switch SW₂. The third switching path 233 of the switching circuit 230 comprises a variable resistor R_{V}. Especially, at each time point, only one of the first switching path 231, the second switching path and the third switching path 233 is activated. In addition, the third switching path 233 may be regarded as the adjustable resistance path.

The switch SW₁ is connected between the ground voltage GND and the node a. The control terminal of the switch SW₁ receives the first mode signal S_{MODE1}. According to the first mode signal S_{MODE1}, the switch SW₁ is controlled to be selectively in a closed state or an opened state. The switch SW₂ is connected between the supply voltage V_{SUPPLY} and the node a. The control terminal of the switch SW₂ receives the second mode signal S_{MODE2}. According to the second mode signal S_{MODE2}, the switch SW₂ is controlled to be selectively in a closed state or an opened state. The first terminal of the variable resistor R_{V} receives the supply voltage V_{SUPPLY}. The second terminal of the variable resistor R_{V} is connected with the node a. The control terminal of the variable resistor R_{V} receives the third mode signal S_{MODE3} and the control signal C_{TRL}. The resistance value of the variable resistor R_{V} can be adjusted according to the control signal C_{TRL}.

When the non-volatile memory 100 is in the deep standby mode, the first mode signal S_{MODE1} is activated, the switch SW₁ is in a closed state, and the first switching path 231 is activated. Meanwhile, the output terminal of the switching circuit 230 is connected with the ground voltage GND. Consequently, the operation voltage V_{DD} provided by the switching circuit 230 is 0V.

When the non-volatile memory 100 is in the normal operation mode, the second mode signal S_{MODE2} is activated, the switch SW₂ is in a closed state, and the second switching path 232 is activated. Meanwhile, the output terminal of the switching circuit 230 is connected with the supply voltage V_{SUPPLY}. Consequently, the operation voltage V_{DD} provided by the switching circuit 230 is equal to the supply voltage V_{SUPPLY}, e.g., 1.2V.

When the non-volatile memory 100 is in the standby mode, the third mode signal S_{MODE3} is activated, the third switching path 233 is activated, and the adjusting period starts. During the adjusting period, the adjusting circuit 220 provides the control signal C_{TRL} to adjust the resistance value of the variable resistor R_{V}. Consequently, the magnitude of the operation voltage V_{DD} is subjected to the change.

When the magnitude of the operation voltage V_{DD} from the output terminal of the switching circuit 230 is identical to the magnitude of the reference voltage V_{REF}, the control signal C_{TRL} is no longer subjected to the change, and the adjusting period is ended. That is, in the standby mode of the non-volatile memory 100, the adjusting circuit 220 adjusts the operation voltage V_{DD} in the adjusting period until the operation voltage V_{DD} is equal to the reference voltage V_{REF}. After the adjusting period, the operation voltage V_{DD} will be maintained at the reference voltage V_{REF}.

FIG. 3B is a schematic circuit diagram illustrating a second exemplary switching circuit of the power control apparatus according to the first embodiment of the present invention. The node a is the output terminal of the switching circuit 230. The voltage at the node a is the operation voltage V_{DD}.

The first switching path 231 of the switching circuit 230 comprises a switching transistor M_{A}. The drain terminal of the switching transistor M_{A} is connected with the node a. The source terminal of the switching transistor M_{A} receives the ground voltage GND. The gate terminal of the switching transistor M_{A} receives the first mode signal S_{MODE1}.

The second switching path 232 of the switching circuit 230 comprises a switching transistor M_{B} and an inverter 401. The source terminal of the switching transistor M_{B} receives the supply voltage V_{SUPPLY}. The drain terminal of the switching transistor M_{B} is connected with the node a. The input terminal of the inverter 401 receives the second mode signal S_{MODE2}. The output terminal of the inverter 401 is connected with the gate terminal of the switching transistor M_{B}.

The third switching path 233 of the switching circuit 230 comprises a switching unit 410 and X resistor units 411˜41X. The switching unit 410 and the X resistor units 411˜41X are collaboratively formed as a variable resistor.

The switching unit 410 comprises a switching transistor M_{C} and an inverter 402. The source terminal of the switching transistor M_{C} receives the supply voltage V_{SUPPLY}. The drain terminal of the switching transistor M_{C} is connected with the node d. The input terminal of the inverter 402 receives the third mode signal S_{MODE3}. The output terminal of the inverter 402 is connected with the gate terminal of the switching transistor M_{C}. When the third mode signal S_{MODE3} is activated, the voltage source of the supply voltage V_{SUPPLY} is connected with the node d through the switching unit 410.

The X resistor units 411˜41X are serially connected between the node d and the node a. The circuitry structures of the X resistor units 411˜41X are identical. The first input terminals of the X resistor units 411˜41X receive the third mode signal S_{MODE3}. The second input terminals of X resistor units 411˜41X respectively receive the corresponding control bits C_{TRL1}˜C_{TRLX} of the control signal C_{TRL}.

For example, the resistor unit 411 comprises a resistance element r₁, a switching transistor M_{D1} and a NAND gate 421. The first terminal of the resistance element r₁ is connected with the source terminal of the switching transistor M_{D1}. The second terminal of the resistance element r₁ is connected with the drain terminal of the switching transistor M_{D1}. The first input terminal of the NAND gate 421 receives the third mode signal S_{MODE3}. The second input terminal of the NAND gate 421 receives the control bit C_{TRL1}. The output terminal of the NAND gate 421 is connected with the gate terminal of the switching transistor M_{D1}. Similarly, the resistor unit 412 receives the third mode signal S_{MODE3} and the control bit C_{TRL2}. In addition, the resistor unit 412 comprises a resistance element r₂, a switching transistor M_{D2} and a NAND gate 422. Similarly, the resistor unit 41X receives the third mode signal S_{MODE3} and the control bit C_{TRLX}. In addition, the resistor unit 41X comprises a resistance element r_{X}, a switching transistor M_{DX} and a NAND gate 42X. Furthermore, the resistance elements r₁˜r_{X} in the X resistor units 411˜41X are connected between the node d and the node a in series.

When the non-volatile memory 100 is in the deep standby mode, the first mode signal S_{MODE1} is activated, the second mode signal S_{MODE2} is not activated, and the third mode signal S_{MODE3} is not activated. The switching transistor M_{A} is turned on. The switching transistor M_{B} is turned off. The switching transistor M_{C} is turned off. Consequently, the first switching path 231 is activated. Meanwhile, the output terminal of the switching circuit 230 is connected with the ground voltage GND. Consequently, the operation voltage V_{DD} provided by the switching circuit 230 is 0V.

When the non-volatile memory 100 is in the normal operation mode, the first mode signal S_{MODE1} is not activated, the second mode signal S_{MODE2} is activated, and the third mode signal S_{MODE3} is not activated. The switching transistor M_{A} is turned off. The switching transistor M_{B} is turned on. The switching transistor M_{C} is turned off. Consequently, the second switching path 232 is activated. Meanwhile, the output terminal of the switching circuit 230 is connected with the supply voltage V_{SUPPLY}. Consequently, the operation voltage V_{DD} provided by the switching circuit 230 is equal to the supply voltage V_{SUPPLY}, e.g., 1.2V.

When the non-volatile memory 100 is in the standby mode, the first mode signal S_{MODE1} is not activated, the second mode signal S_{MODE2} is not activated, and the third mode signal S_{MODE3} is activated. The switching transistor M_{A} is turned off. The switching transistor M_{B} is turned off. The switching transistor M_{C} is turned on. Consequently, the third switching path 233 is activated, and the adjusting period starts. During the adjusting period, the adjusting circuit 220 provides the control signal C_{TRL} to adjust the resistance value of the variable resistor R_{V}. Consequently, the magnitude of the operation voltage V_{DD} is subjected to the change.

For example, in case that all of the X control bits C_{TRL1}˜C_{TRLX} are in the logic high level state, the switching transistors M_{D1}˜M_{DX} in the resistor units 411˜41X are all turned on. Since the resistance elements r₁˜r_{X} in the resistor units 411˜41X are short-circuited by the switching transistors M_{D1}˜M_{DX}, the resistance value of the variable resistor R_{V} is very low. Under this circumstance, the magnitude of the operation voltage V_{DD} outputted from the output terminal of the switching circuit 230 is approximately identical to the magnitude of the supply voltage V_{SUPPLY}.

As the number of the X control bits C_{TRL1}˜C_{TRLX} in the logic high level state gradually decreases, the number of the resistance elements r₁˜r_{X} in the resistor units 411˜41X connected between the node d and the node a in series are gradually increased. Consequently, the resistance value of the variable resistor R_{V} is gradually increased. Under this circumstance, the magnitude of the operation voltage V_{DD} outputted from the output terminal of the switching circuit 230 is gradually decreased. When the magnitude of the operation voltage V_{DD} from the output terminal of the switching circuit 230 is identical to the magnitude of the reference voltage V_{REF}, the control signal C_{TRL} is no longer subjected to the change, and the adjusting period is ended. That is, in the standby mode of the non-volatile memory 100, the adjusting circuit 220 adjusts the operation voltage V_{DD} in the adjusting period until the operation voltage V_{DD} is equal to the reference voltage V_{REF}. After the adjusting period, the operation voltage V_{DD} will be maintained at the reference voltage V_{REF}.

It is noted that the circuitry structures of the first switching path 231, the second switching path 232 and the third switching path 233 are not restricted. For example, the circuitry structures of the first switching path 231, the second switching path 232 and the third switching path 233 may be properly modified according to the logic level state of the mode indicating signal S_{MODE}. For example, it is assumed that the second mode signal S_{MODE2} is in the logic low level state when the second mode signal S_{MODE2} is activated. Under this circumstance, the inverter 401 in the second switching path 232 is omitted, and the gate of the switching transistor M_{B} receives the second mode signal S_{MODE2}.

Similarly, the inverter 402 and the NAND gates 421˜42X in the third switching path 233 may be properly modified by other logic gates according to the logic level state of the mode indicating signal S_{MODE} and the logic level state of the control circuit C_{TRL}. In a variant example of FIG. 3B, the switching unit 410 in the third switching path 233 maybe omitted. That is, the third switching path 233 of the switching circuit 230 comprises X resistor units 411˜41X only. The X resistor units 411˜41X are serially connected between the node d and the node a. In addition, the node d receives the supply voltage V_{SUPPLY}.

FIG. 3C is a schematic circuit diagram illustrating a third exemplary switching circuit of the power control apparatus according to the first embodiment of the present invention. The node a is the output terminal of the switching circuit 230. The voltage at the node a is the operation voltage V_{DD}. The circuitry structures of the first switching path 231 and the second switching path 232 are identical to those of FIG. 3B, and not redundantly described herein. The third switching path 233 of the switching circuit 230 comprises X resistor units 461˜46X. The X resistor units 461˜46X are collaboratively formed as a variable resistor R_{V}. The X resistor units 461˜46X are connected between the node e and the node a in parallel. The node e receives the supply voltage V_{SUPPLY}. The circuitry structures of the X resistor units 461˜46X are identical.

For example, the resistor unit 461 comprises a resistance element r₁, a switching transistor M_{E1} and a NAND gate 451. The source terminal of the switching transistor M_{E1} is connected with the node e. The drain terminal of the switching transistor M_{E1} is connected with the first terminal of the resistance element r₁. The second terminal of the resistance element r₁ is connected with the node a. The first input terminal of the NAND gate 451 receives the third mode signal S_{MODE3}. The second input terminal of the NAND gate 451 receives the control bit C_{TRL1}. The output terminal of the NAND gate 451 is connected with the gate terminal of the switching transistor M_{E1}. Similarly, the resistor unit 462 receives the third mode signal S_{MODE} and the control bit C_{TRL2}. In addition, the resistor unit 462 comprises a resistance element r₂, a switching transistor M_{E2} and a NAND gate 452. Similarly, the resistor unit 46X receives the third mode signal S_{MODE} and the control bit C_{TRLX}. In addition, the resistor unit 46X comprises a resistance element r_{X}, a switching transistor M_{EX} and a NAND gate 45X.

When the non-volatile memory 100 is in the deep standby mode, the first switching path 231 is activated. Meanwhile, the output terminal of the switching circuit 230 is connected with the ground voltage GND. Consequently, the operation voltage V_{DD} provided by the switching circuit 230 is 0V.

When the non-volatile memory 100 is in the normal operation mode, the second switching path 232 is activated. Meanwhile, the output terminal of the switching circuit 230 is connected with the supply voltage V_{SUPPLY}. Consequently, the operation voltage V_{DD} provided by the switching circuit 230 is equal to the supply voltage V_{SUPPLY}, e.g., 1.2V.

When the non-volatile memory 100 is in the standby mode, the third mode signal S_{MODE3} is activated, and the third switching path 233 is activated, and the adjusting period starts. During the adjusting period, the adjusting circuit 220 provides the control signal C_{TRL} to adjust the resistance value of the variable resistor R_{V}. Consequently, the magnitude of the operation voltage V_{DD} is subjected to the change.

For example, in case that all of the X control bits C_{TRL1}˜C_{TRLX} are in the logic high level state, the switching transistors M_{E1}˜M_{EX} in the resistor units 411˜41X are all turned on. Since the resistance elements r₁˜r_{X} in the resistor units 411˜41X are connected between the node e and the node a in parallel, the resistance value of the variable resistor R_{V} is the lowest.

As the number of the X control bits C_{TRL1}˜C_{TRLX} in the logic high level state gradually decreases, the number of the resistance elements r₁˜r_{X} in the resistor units 411˜41X connected in parallel between the node e and the node a is decreased. Consequently, the resistance value of the variable resistor R_{V} is gradually increased. Under this circumstance, the magnitude of the operation voltage V_{DD} outputted from the output terminal of the switching circuit 230 is gradually decreased. When the magnitude of the operation voltage V_{DD} from the output terminal of the switching circuit 230 is identical to the magnitude of the reference voltage V_{REF}, the control signal C_{TRL} is no longer subjected to the change, and the adjusting period is ended. That is, in the standby mode of the non-volatile memory 100, the adjusting circuit 220 adjusts the operation voltage V_{DD} in the adjusting period until the operation voltage V_{DD} is equal to the reference voltage V_{REF}. After the adjusting period, the operation voltage V_{DD} will be maintained at the reference voltage V_{REF}.

From the above descriptions, the present invention provides a power control apparatus for a non-volatile memory. When the non-volatile memory is operated in the normal operation mode, the operation voltage V_{DD} provided by the power control apparatus 160 is equal to the supply voltage V_{SUPPLY}. When the non-volatile memory is operated in the deep standby mode, the operation voltage V_{DD} provided by the power control apparatus 160 is equal to the ground voltage (0V). Meanwhile, it may be regarded that the power control apparatus 160 does not provide the operation voltage V_{DD}. When the non-volatile memory is operated in the standby mode, the operation voltage V_{DD} provided by the power control apparatus 160 is lower than the supply voltage V_{SUPPLY}. Since the operation voltage V_{DD} provided by the power control apparatus 160 is lower than the supply voltage V_{SUPPLY} when the non-volatile memory is in the standby mode, the power loss in the standby mode can be effectively reduced.

In the power control apparatus 160 of the first embodiment, the magnitude of the operation voltage V_{DD} is adjusted in a single adjusting period when the non-volatile memory is operated in the standby mode. Consequently, the operation voltage V_{DD} is equal to the magnitude of the reference voltage V_{REF}. However, if the non-volatile memory 100 is operated in the standby mode for a long time or the ambient temperature rises, the resistance value (R_{EQ}) of the load 250 in the non-volatile memory 100 will change. Under this circumstance, the operation voltage V_{DD} increases, and the power loss increases. It is noted that the signal generator 226 in the adjusting circuit 220 may be modified. Consequently, when the non-volatile memory is operated in the standby mode, the signal generator 226 can activate the adjustment signal ADJ many times. In addition, the operation voltage V_{DD} is correspondingly adjusted by the controller 222.

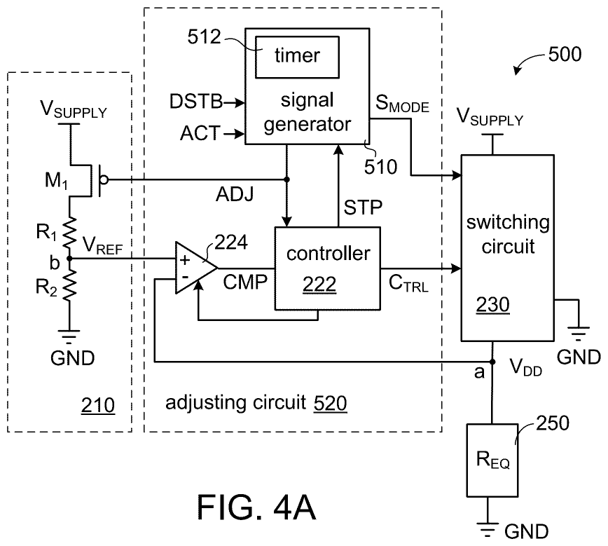

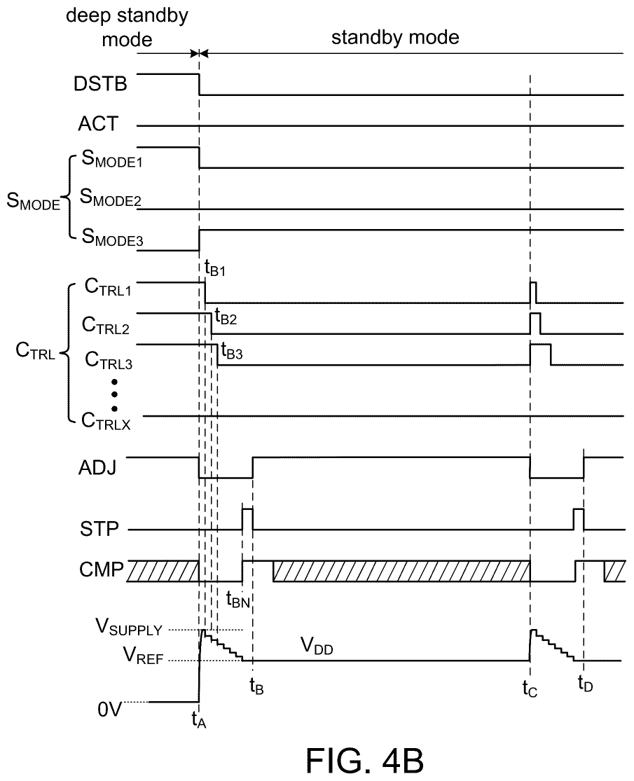

FIG. 4A is a schematic circuit diagram illustrating a power control apparatus for the non-volatile memory according to a second embodiment of the present invention. FIG. 4B is a schematic timing waveform diagram illustrating associated signals of the power control apparatus according to the second embodiment of the present invention.

In comparison with the power control apparatus 160 of the first embodiment, the signal generator 510 of the adjusting circuit 520 in the power control apparatus 500 of the second embodiment further includes a timer 512. For brevity, only the operating principles of the signal generator 510 will be described as follows.

In this embodiment, during the standby mode, the timer 512 periodically activates the adjustment signal ADJ. In other words, whenever the adjustment signal ADJ is activated, an adjusting period begins. For example, after the timer 512 counts time for a specified time period (e.g., 1 second), the signal generator 510 starts an adjusting period. That is, when the non-volatile memory 100 is in the standby mode, the signal generator 510 periodically starts an adjusting period at the interval of the specified time period through the control of the timer 512. Consequently, the operation voltage V_{DD} can be periodically adjusted accordingly to ensure that the magnitude of the operation voltage V_{DD} is identical to the magnitude of the reference voltage V_{REF} when the adjusting period is ended. For example, the timer 512 is implemented with an oscillator. The logic level state of the output signal from the oscillator is switched at the interval of the specified time period. Consequently, the signal generator 510 is controlled to activate the adjustment signal ADJ and start the adjusting period.

Please refer to FIG. 4B again. At the time point t_{A}, the non-volatile memory 100 enters the standby mode. Meanwhile, the signal generator 510 activate the adjustment signal ADJ to start an adjusting period. Similarly, in the adjusting period, the control signal C_{TRL} is changed by the controller 222, and thus the operation voltage V_{DD} is gradually changed. Until the magnitude of the operation voltage V_{DD} is equal to the magnitude of the reference voltage V_{REF}, the comparison signal CMP is activated, and the stop signal STP is activated. Consequently, at the time point t_{B}, the adjusting period is ended. After a specified time period (e.g., at the time point t_{C}), the signal generator 510 starts another adjusting period under the control of the timer 512. Consequently, in the adjusting period between the time point t_{D} and the time point t_{E}, the operation voltage V_{DD} is gradually adjusted until the magnitude of the operation voltage V_{DD} is equal to the magnitude of the reference voltage V_{REF}.

From the above descriptions, the adjustment signal ADJ is periodically adjusted by the power control apparatus 500 of the second embodiment. The magnitude of the operation voltage V_{DD} provided by the power control apparatus 500 can be maintained at the reference voltage V_{REF}. Consequently, the power loss in the standby mode can be effectively reduced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power control apparatus for a non-volatile memory, the power control apparatus comprising:
a reference voltage generator receiving an adjustment signal, wherein when the adjustment signal is activated, the reference voltage generator provides a reference voltage;
an adjusting circuit generating a mode indicating signal, the adjustment signal and a control signal, wherein the mode indicating signal indicates that the non-volatile memory is in a deep standby mode, a normal operation mode or a standby mode, wherein the adjusting circuit is connected with the reference voltage generator, and the adjusting circuit receives the reference voltage; and
a switching circuit receiving a supply voltage, a ground voltage, the mode indicating signal and the control signal, wherein an output terminal of the switching circuit is connected with a first node, a voltage at the first node is an operation voltage, and a load is connected with the first node,
wherein the switching circuit comprises a first switching path, a second switching path and a third switching path, wherein the reference voltage is lower than the supply voltage, and the reference voltage is higher than the ground voltage,
wherein when the non-volatile memory is in the deep standby mode, the first switching path is activated according to the mode indicating signal, so that the ground voltage is connected with the first node and the operation voltage is equal to the ground voltage,
wherein when the non-volatile memory is in the normal operation mode, the second switching path is activated according to the mode indicating signal, so that the supply voltage is connected with the first node and the operation voltage is equal to the supply voltage,
wherein the third switching path is an adjustable resistance path, wherein when the non-volatile memory is in the standby mode, the adjustment signal is activated, and the third switching path is activated according to the mode indicating signal, so that the third switching path is connected between the supply voltage and the first node, wherein a resistance value of the adjustable resistance path is adjusted by the adjusting circuit according to the control signal until a magnitude of the operation voltage is equal to a magnitude of the reference voltage.

2. The power control apparatus as claimed in claim 1, wherein the non-volatile memory comprises:
a processor generating a driving signal;
a memory cell array;
a word line driver connected with the processor, and connected with plural word lines of the memory cell array;
a bit line driver connected with the processor, and connected with plural bit lines of the memory cell array, wherein the word line driver and the bit line driver receive the driving signal, and the word line driver and the bit line driver activate a corresponding word line of the plural word lines and a corresponding bit line of the plural bit lines according to the driving signal; and
a data sensor connected with the bit line driver,
wherein the power control apparatus provides the operation voltage to the processor, the word line driver, the bit line driver and the data sensor, and the processor, the word line driver, the bit line driver and the data sensor are included in the load.

3. The power control apparatus as claimed in claim 1, wherein the reference voltage generator comprises:
a transistor, wherein a source terminal of the transistor receives the supply voltage, and a gate terminal of the transistor receives the adjustment signal, wherein when the adjustment signal is activated, the transistor is turned on;
a first resistor, wherein a first terminal of the first resistor is connected with a drain terminal of the transistor, and a second terminal of the first resistor is connected with a second node; and
a second resistor, wherein a first terminal of the second resistor is connected with the second node, and a second terminal of the second resistor receives the ground voltage,
wherein a voltage at the second node is the reference voltage.

4. The power control apparatus as claimed in claim 1, wherein the adjusting circuit comprises:
a signal generator receiving a deep standby signal and an operation signal, and generating the mode indicating signal and the adjustment signal according to the deep standby signal and the operation signal;
a comparator, wherein a first input terminal of the comparator receives the reference voltage, a second input terminal of the comparator is connected with the first node to receive the operation voltage, and an output terminal of the comparator generates a comparison signal; and
a controller receiving the adjustment signal and the comparison signal, and generating a control signal and a stop signal,
wherein when the non-volatile memory is in the standby mode, the signal generator activates the adjustment signal to start an adjusting period, and the controller changes the control signal in the adjusting period, wherein when the comparison signal is activated, the controller stops changing the control signal, and the controller activates the stop signal, so that the adjustment signal is inactivated by the signal generator and the adjusting period is ended.

5. The power control apparatus as claimed in claim 4, wherein as the control signal is changed by the controller, the resistance value of the adjustable resistance path is adjusted according to the control signal, wherein when the magnitude of the operation voltage is equal to the magnitude of the reference voltage, the comparison signal is activated by the comparator.

6. The power control apparatus as claimed in claim 4, wherein the signal generator includes a timer; and wherein during the standby mode, the timer periodically activates the adjustment signal to start the adjusting period and the operation voltage can be periodically adjusted accordingly to ensure that a magnitude of the operation voltage is identical to a magnitude of the reference voltage when the adjusting period is ended.

7. The power control apparatus as claimed in claim 1, wherein the mode indicating signal contains a first mode signal, a second mode signal and a third mode signal, wherein the non-volatile memory is in the deep standby mode when the first mode signal is activated, the non-volatile memory is in the normal operation mode when the second mode signal is activated, and the non-volatile memory is in the standby mode when the third mode signal is activated.

8. The power control apparatus as claimed in claim 7, wherein the first switching path comprises a first switch, the second switching path comprises a second switch, and the third switching path comprises a variable resistor, wherein a first terminal of the first switch receives the ground voltage, a second terminal of the first switch is connected with the first node, and a control terminal of the first switch receives the first mode signal, wherein a first terminal of the second switch receives the supply voltage, a second terminal of the second switch is connected with the first node, and a control terminal of the second switch receives the second mode signal, wherein a first terminal of the variable resistor receives the supply voltage, a second terminal of the variable resistor is connected with the first node, and control terminals of the variable resistor receives the third mode signal and the control signal.

9. The power control apparatus as claimed in claim 8, wherein when the first mode signal is activated, the first switch is in a closed state, and the ground voltage is connected with the first node, wherein when the second mode signal is activated, the second switch is in a closed state, and the supply voltage is connected with the first node, wherein when the third mode signal is activated, the variable resistor is connected between the supply voltage and the first node, and a resistance value of the variable resistor is adjusted according to the control signal.

10. The power control apparatus as claimed in claim 7, wherein the first switching path comprises a first switching transistor, the second switching path comprises a second switching transistor, and the third switching path comprises a variable resistor.

11. The power control apparatus as claimed in claim 10, wherein a drain terminal of the first switching transistor is connected with the first node, and a source terminal of the first switching transistor receives the ground voltage, wherein when the first mode signal is activated, the first switching transistor is turned on, and the ground voltage is connected with the first node.

12. The power control apparatus as claimed in claim 10, wherein a drain terminal of the second switching transistor is connected with the first node, and a source terminal of the second switching transistor receives the supply voltage, wherein when the second mode signal is activated, the second switching transistor is turned on, and the supply voltage is connected with the first node.

13. The power control apparatus as claimed in claim 10, wherein the control signal contains X control bits, and the control signal has an initial value when the non-volatile memory is switched from the deep standby mode to the standby mode or switched from the normal operation mode to the standby mode, when the magnitude of the operation voltage is greater than the magnitude of the reference voltage, the adjusting circuit gradually adjusts the logic level state of the X control bits from the initial value, such that the resistance value of the variable resistor gradually increases, and the magnitude of the operation voltage gradually decreases and finally equals the magnitude of the reference voltage.

14. The power control apparatus as claimed in claim 10, wherein the control signal contains X control bits, and the third switching path comprises:
a switching unit, wherein a first terminal of the switching unit receives the supply voltage, a second terminal of the switching unit is connected with a third node, and a control terminal of the switching unit receives the third mode signal, wherein when the third mode signal is activated, the supply voltage is connected with third node through the switching unit; and
X resistor units connected between the third node and the first node in series, wherein each of the X resistor units receives a corresponding control bit of the X control bits, and each resistor unit of the X resistor units comprises:
a logic circuit, wherein a first input terminal of the logic circuit receives the third mode signal, and a second input terminal of the logic circuit receives the corresponding control bit of the control signal;
a switching transistor; and
a resistance element, wherein a first terminal of the resistance element is connected with a source terminal of the switching transistor, a second terminal of the resistance element is connected with a drain terminal of the switching transistor, and a gate terminal of the switching transistor is connected with an output terminal of the logic circuit,
wherein when the third mode signal is activated and the control signal is gradually changed, the number of the resistance elements in the X resistor units connected in series between the third node and the first node is gradually increased, so that the resistance value of the adjustable resistance path is gradually increased.

15. The power control apparatus as claimed in claim 10, wherein the control signal contains X control bits, and the third switching path comprises:
X resistor units connected between the supply voltage and the first node in series, wherein each of the X resistor units receives the third mode signal and a corresponding control bit of the X control bits, and each resistor unit of the X resistor units comprises:
a logic circuit, wherein a first input terminal of the logic circuit receives the third mode signal, and a second input terminal of the logic circuit receives the corresponding control bit of the control signal;
a switching transistor; and
a resistance element, wherein a first terminal of the resistance element is connected with a source terminal of the switching transistor, a second terminal of the resistance element is connected with a drain terminal of the switching transistor, and a gate terminal of the switching transistor is connected with an output terminal of the logic circuit,
wherein when the third mode signal is activated and the control signal is gradually changed, the number of the resistance elements in the X resistor units connected in series between the third node and the first node is gradually increased, so that the resistance value of the adjustable resistance path is gradually increased.

16. The power control apparatus as claimed in claim 10, wherein the control signal contains X control bits, and the third switching path comprises:
X resistor units connected between the supply voltage and the first node in parallel, wherein each of the X resistor units receives the third mode signal and a corresponding control bit of the X control bits, and each resistor unit of the X resistor units comprises:
a logic circuit, wherein a first input terminal of the logic circuit receives the third mode signal, and a second input terminal of the logic circuit receives the corresponding control bit of the control signal;
a switching transistor; and
a resistance element, wherein a source terminal of the switching transistor receives the supply voltage, a gate terminal of the switching transistor is connected with an output terminal of the logic circuit, a drain terminal of the switching transistor is connected with a first terminal of the resistance element, and a second terminal of the resistance element is connected with the first node,
wherein when the third mode signal is activated and the control signal is gradually changed, the number of resistance elements in the X resistor units connected in parallel between the supply voltage and the first node is gradually decreased, so that the resistance value of the adjustable resistance path is gradually increased.
